(19) United States
(12) Patent Application Publication
(10) Pub. No.: US 2026/0076009 A1
(43) Pub. Date: Mar. 12, 2026

(54) ELECTRONIC DEVICE

(71) Applicant: InnoLux Corporation, Miao-Li County (TW)

(72) Inventors: Shun-Yuan HU, Miao-Li County (TW); Jia-Huei LIN, Miao-Li County (TW); Li-Wei MAO, Miao-Li County (TW)

(21) Appl. No.: 19/294,779

(22) Filed: Aug. 8, 2025

Related U.S. Application Data
(60) Provisional application No. 63/692,270, filed on Sep. 9, 2024.

(30) Foreign Application Priority Data
Mar. 19, 2025 (CN) 202510324803.0

(51) Int. Cl. H10H 29/855; H01L 25/075; H10H 29/14; H10H 29/45; H10H 29/80; H10H 29/856

(52) U.S. Cl. CPC H10H 29/855; H10H 29/142; H10H 29/45; H10H 29/842; H10H 29/856; H10W 90/00

(57) ABSTRACT

An electronic device includes: a first substrate; a second substrate disposed adjacent to the first substrate, wherein a tiling gap is between the first substrate and the second substrate; a plurality of light emitting elements respectively disposed on the first substrate and the second substrate; a cover layer disposed on the first substrate and the second substrate and covering the plurality of light emitting elements; and a low transmittance film disposed on the cover layer, wherein the low transmittance film and the tiling gap are overlapped in a normal direction of the electronic device.

### CROSS-REFERENCE TO RELATED APPLICATIONS

This application claims the benefits of the Chinese Patent Application Serial Number 202510324803.0, filed on Mar. 19, 2025, the subject matter of which is incorporated herein by reference.

This application claims the benefit of filing date of U.S. Provisional Application Ser. No. 63/692,270, filed Sep. 9, 2024 under 35 USC § 119(e)(1).

### BACKGROUND

### Field

The present disclosure provides an electronic device and, more specifically, an electronic device with plural substrates and a low transmittance film.

### Description of Related Art

As technology continues to advance and to meet various needs, manufacturers continue to improve and research display devices. The application of display devices is no longer limited to monitors, mobile phones, notebook computers, and televisions. For example, the tiled electronic device can be developed to expand the application of display devices to movie walls, billboards and other electronic devices used to display large images.

However, the tiled electronic device still has obvious tiling gap and other display taste defects. Therefore, it is desirable to provide an electronic device in order to improve the conventional defects.

### SUMMARY

The present disclosure provides an electronic device, comprising: a first substrate; a second substrate disposed adjacent to the first substrate, wherein a tiling gap is between the first substrate and the second substrate; a plurality of light emitting elements respectively disposed on the first substrate and the second substrate; a cover layer disposed on the first substrate and the second substrate and covering the plurality of light emitting elements; and a low transmittance film disposed on the cover layer, wherein the low transmittance film and the tiling gap are overlapped in a normal direction of the electronic device.

Other novel features of the disclosure will become more apparent from the following detailed description when taken in conjunction with the accompanying drawings.

### BRIEF DESCRIPTION OF DRAWINGS

FIG. 1A is a top schematic view of a part of an electronic device according to one embodiment of the present disclosure.

FIG. 1B is a cross-sectional schematic view along the line A-A′ of FIG. 1A.

FIG. 2 is a cross-sectional schematic view of a part of an electronic device according to one embodiment of the present disclosure.

FIG. 3 is a cross-sectional schematic view of a part of an electronic device according to one embodiment of the present disclosure.

FIG. 4 is a cross-sectional schematic view of a part of an electronic device according to one embodiment of the present disclosure.

FIG. 5 is a cross-sectional schematic view of a part of an electronic device according to one embodiment of the present disclosure.

FIG. 6 is a cross-sectional schematic view of a part of an electronic device according to one embodiment of the present disclosure.

FIG. 7 is a cross-sectional schematic view of a part of an electronic device according to one embodiment of the present disclosure.

### DETAILED DESCRIPTION

The following is a detailed description of the electronic device according to the embodiment of the present disclosure. It should be understood that the following description provides many different embodiments for implementing different aspects of some embodiments of the present disclosure. Specific examples of each component and its configuration are described below to simplify the embodiments of the present disclosure. Of course, these are only examples and are not intended to limit the present disclosure. In addition, similar and/or corresponding reference numerals may be used to identify similar and/or corresponding elements in different embodiments to clearly describe the present disclosure. However, the use of these similar and/or corresponding reference numerals is only for the purpose of simply and clearly describing some embodiments of the present disclosure, and does not imply any correlation between the different embodiments and/or structures discussed.

The embodiments of the present disclosure may be understood in conjunction with the drawings, which are also considered part of the disclosure. It should be understood that the drawings of the present disclosure are not drawn to scale, and in fact, the size of the elements may be arbitrarily enlarged or reduced in order to clearly show the features of the present disclosure. In addition, the directional terms mentioned in the present disclosure, such as “up”, “down”, “front”, “back”, “left”, “right”, etc., are only referenced to the directions of the accompanying drawings. Therefore, the directional terms used are for illustration and are not intended to limit the present disclosure. In the accompanying drawings, each diagram depicts the general characteristics of the methods, structures and/or materials used in a particular embodiment. However, these diagrams should not be interpreted as defining or limiting the scope or nature covered by these embodiments. For example, for the sake of clarity, the relative size, thickness and position of each layer, region and/or structure may be reduced or enlarged.

One structure (or layer, component, or substrate) described in the present disclosure is located on/above another structure (or layer, component, or substrate). This may mean that the two structures are adjacent and directly connected, or the two structures are adjacent rather than directly connected. Indirect connection means that there is at least one intermediary structure (or intermediary layer, intermediary component, intermediary substrate, or intermediary spacer) between two structures. The lower surface of one structure is adjacent to or directly connected to the upper surface of the intermediary structure, and the upper surface of another structure is adjacent to or directly connected to the lower surface of the intermediary structure. The intermediary structure can be composed of a single-layer or multi-layer solid structure or a non-solid structure, and there is no limit. In the present disclosure, when a structure is disposed “on” another structure, it may mean that the structure is “directly” on the other structure, or that the structure is “indirectly” on the other structure, that is, at least one structure is also sandwiched between the structure and the other structure. In the present disclosure, the term “relatively disposed” or “disposed relative to . . . ” refers to, for example, that the elements substantially overlap with each other, but the present disclosure is not limited thereto.

In addition, it should be understood that the ordinal numbers used in the description and the claims, such as “first”, “second”, etc., are intended only to describe the elements claimed and imply or represent neither that the (these) elements have any proceeding ordinals, nor that sequence between one claimed element and another claimed element or between steps of a manufacturing method. The use of these ordinals is merely to differentiate one claimed element having a certain designation from another claimed element having the same designation. The same words may not be used in the claim and the description. For example, the first element in the description may be the second element in the claim.

In some embodiments of the present disclosure, terms related to joining and connecting, such as “connection”, “interconnection”, etc., unless otherwise defined, may mean that two structures are in direct contact, or may also mean that two structures are not in direct contact where other structures are located between these two structures. The terms “joint” and “connection” can also include situations where both structures are movable, or where both structures are fixed. In addition, the terms “coupling” include any direct and indirect means of connection.

In the present specification, the terms, such as “about”, “substantially”, or “approximately”, are generally interpreted as within 10%, 5%, 3%, 2%, 1%, or 0.5% of a given value or range. Unless otherwise stated, when a value is “in a range from a first value to a second value” or “in a range between a first value and a second value”, the value can be the first value, the second value, or another value between the first value and the second value. In addition, any two values or directions used for comparison may have certain errors. If the first value is equal to the second value, it implies that there may be an error of about 10% between the first value and the second value. If the first direction is perpendicular to the second direction, the angle between the first direction and the second direction may be between 80° and 100°. If the first direction is parallel to the second direction, the angle between the first direction and the second direction may be between 0° and 10°. In the present disclosure, the term “the given range is from the first value to the second value” and “the given range falls within the range of the first value to the second value” mean that the given range includes the first value, the second value and another value between the first value and the second value.

Furthermore, according to some embodiments of the present disclosure, the thickness, the length, the width, or the distance and angle between elements may be measured by using an optical microscope (OM), scanning electron microscope (SEM), film thickness profiler (α-step), ellipsometer, or other suitable methods. More specifically, according to some embodiments, a scanning electron microscope can be used to obtain a cross-sectional image of the structure and measure the thickness, length, width of each element or the distance and angle between elements. In the present disclosure, the transmittance can be measured using a NIPPON haze meter NDH 7000.

In the specification and the appended claims of the present disclosure, certain words are used to refer to specific elements. Those skilled in the art should understand that electronic device manufacturers may refer to the same components by different names. The present specification does not intend to distinguish between elements that have the same function but have different names. In the following description and claims, words such as “comprising”, “including”, “containing”, and “having” are open-ended words, so they should be interpreted as meaning “containing but not limited to . . . ”. Therefore, when the terms “comprising”, “including”, “containing” and/or “having” are used in the description of the present disclosure, they specify the existence of corresponding features, regions, steps, operations and/or components, but do not exclude the existence of one or more corresponding features, regions, steps, operations and/or components.

It should be noted that the following embodiments may be implemented by replacing, reorganizing, or mixing features of several different embodiments without departing from the spirit of the present disclosure to implement other embodiments. The features of the various embodiments may be mixed and matched as desired as long as they do not violate the spirit of the invention or conflict with each other.

In the present specification, except otherwise specified, the terms (including technical and scientific terms) used herein have the meanings generally known by a person skilled in the art. It should be noted that, except otherwise specified in the embodiments of the present disclosure, these terms (for example, the terms defined in the generally used dictionary) should have the meanings identical to those known in the art, the background of the present disclosure or the context of the present specification, and should not be read by an ideal or over-formal way.

The electronic device of the present disclosure may include electronic components, and the electronic components can include passive components, active components or a combination thereof, such as capacitors, resistors, inductors, varactor diodes, variable capacitors, filters, diodes, transistors, sensors, microelectromechanical system components (MEMS), liquid crystal chips, etc., but the present disclosure is not limited thereto. The diode may include light emitting diode or non-light emitting diode. The diode includes a P-N junction diode, a PIN diode or a constant current diode. The light emitting diode may include, for example, an organic light emitting diode (OLED), a mini LED, a micro LED, a quantum dot LED, fluorescence, phosphors, other suitable material or a combination thereof, but the present disclosure is not limited thereto. The sensor may include, for example, a capacitive sensor, an optical sensor, an electromagnetic sensor, a fingerprint sensor (FPS), a touch sensor, an antenna or a pen sensor, but the present disclosure is not limited thereto.

The electronic device may include an imaging device, a laminating device, a display device, a backlight device, an antenna device, a tiled device, a touch electronic device (a touch display), a curved electronic device (a curved display) or a non-rectangular electronic device (a free shape display), but the present disclosure is not limited thereto. The electronic device may include, for example, liquid crystals, light emitting diodes, fluorescence, phosphors, other suitable display media, or a combination thereof, but the present disclosure is not limited thereto. The display device may be a non-self-luminous display device or a self-luminous display device. The antenna device may be a liquid crystal antenna device or a non-liquid crystal antenna device. The sensing device may be a sensing device that can sense capacitance, light, heat energy or ultrasonic waves. But, the present disclosure is not limited thereto. The tiled device may be, for example, a tiled display device or a tiled antenna device, but is not limited thereto. The electronic device may be a bendable or flexible electronic device. It should be noted that the electronic device may be any permutation and combination of the above, but not limited to this. In addition, the shape of the electronic device may be rectangular, circular, polygonal, or having a shape with curved edges or other suitable shapes. The electronic device may have peripheral systems such as drive systems, control systems, light source systems, shelf systems, etc. to support the display device, the antenna device or the tiled device. In the following, the display device will be used as an electronic device to illustrate the content of the present disclosure, but the present disclosure is not limited thereto. In other embodiments, the electronic device may be any combinations of the above.

It should be noted that the following embodiments may be implemented by replacing, reorganizing, or mixing features of several different embodiments without departing from the spirit of the present disclosure to implement other embodiments. The features of the various embodiments may be mixed and matched as desired as long as they do not violate the spirit of the invention or conflict with each other. It should be noted that the technical solutions provided in the following different embodiments can be replaced, combined or mixed with each other to form another embodiment without violating the spirit of the present disclosure.

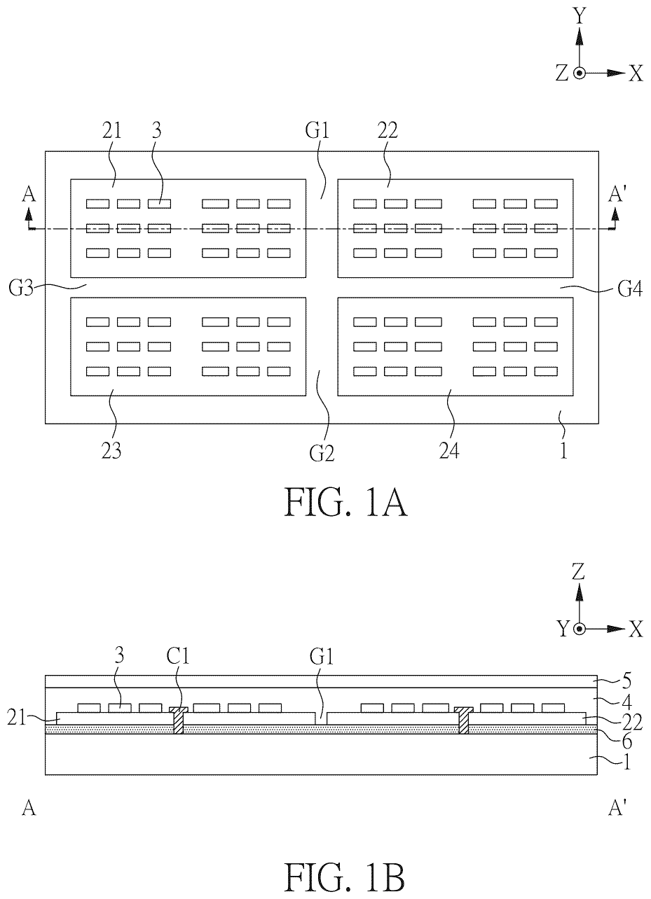

FIG. 1A is a top schematic view of a part of an electronic device according to one embodiment of the present disclosure. FIG. 1B is a cross-sectional schematic view along the line A-A′ of FIG. 1A.

In one embodiment of the present disclosure, as shown in FIG. 1A and FIG. 1B, the electronic device may comprise: a first substrate 21; a second substrate 22 disposed adjacent to the first substrate 21, wherein a tiling gap (for example, a first tiling gap G1) is between the first substrate 21 and the second substrate 22; a plurality of light emitting elements 3 respectively disposed on the first substrate 21 and the second substrate 22; a cover layer 4 disposed on the first substrate 21 and the second substrate 22 and covering the plurality of light emitting elements 3; and a low transmittance film 5 disposed on the cover layer 4, wherein the low transmittance film 5 and the tiling gap (for example, the first tiling gap G1) are overlapped in a normal direction Z of the electronic device. By setting the low transmittance film 5 to be overlapped with the tiling gap (for example, the first tiling gap G1), the tiling gap (for example, the first tiling gap G1) observed by the human eyes can be reduced, thereby achieving the effect of improving the display taste.

In one embodiment of the present disclosure, as shown in FIG. 1A, the electronic device may further comprise a third substrate 23 and a fourth substrate 24, and the third substrate 23 and the fourth substrate 24 are adjacently disposed, wherein the plurality of light emitting elements 3 may be further disposed on the third substrate 23 and the fourth substrate 24. In one embodiment of the present disclosure, as shown in FIG. 1A, the first substrate 21 and the second substrate 22 are arranged along a first direction X, the third substrate 23 and the fourth substrate 24 are also arranged along the first direction X, the first substrate 21 and the third substrate 23 are arranged along a second direction Y, and the second substrate 22 and the fourth substrate 24 are also arranged along the second direction Y, wherein the first direction X is, for example, perpendicular to the second direction Y. Thus, in one embodiment, as shown in FIG. 1A, the first substrate 21, the second substrate 22, the third substrate 23 and the fourth substrate 24 may be arranged in an array, for example, a 2×2 array, but the present disclosure is not limited thereto. In the present disclosure, the electronic device shown in FIG. 1A comprises four substrates (for example, the first substrate 21, the second substrate 22, the third substrate 23 and the fourth substrate 24) as an example, but the present disclosure is not limited thereto. In other embodiments, the numbers of the substrates may be adjusted (for example, increased or decreased) according to the needs.

In one embodiment of the present disclosure, as shown in FIG. 1A, a second tiling gap G2 is between the third substrate 23 and the fourth substrate 24, a third tiling gap G3 is between the first substrate 21 and the third substrate 23, and a fourth tiling gap G4 is between the second substrate 22 and the fourth substrate 24, wherein the first tiling gap G1 and the second tiling gap G2 extend along the second direction Y and are connected to each other, and the third tiling gap G3 and the fourth tiling gap G4 extend along the first direction X and are connected to each other. In the present disclosure, in the normal direction Z of the electronic device, the low transmittance film 5 may be overlapped with the first tiling gap G1, the second tiling gap G2, the third tiling gap G3 and the fourth tiling gap G4. Thus, the tiling gaps (for example, the first tiling gap G1, the second tiling gap G2, the third tiling gap G3 and the fourth tiling gap G4) observed by the human eyes can be reduced, thereby achieving the effect of improving the display taste.

In one embodiment of the present disclosure, as shown in FIG. 1B, in the normal direction Z of the electronic device, the cover layer 4 and the first tiling gap G1 are overlapped, and the cover layer 4 may be further disposed in the first tiling gap G1. Similarly, as shown in FIG. 1A and FIG. 1B, in the normal direction Z of the electronic device, the cover layer 4 may also be overlapped with the second tiling gap G2, the third tiling gap G3 and the fourth tiling gap G4, and the cover layer 4 may also be disposed in the second tiling gap G2, the third tiling gap G3 and the fourth tiling gap G4, but the present disclosure is not limited thereto. The cover layer 4 may also be used to protect the light emitting elements 3 to reduce the contact of the light emitting element 3 with the outside air or moisture, thereby reducing the risk of deterioration of the light emitting elements 3.

In the present disclosure, the materials of the first substrate 21, the second substrate 22, the third substrate 23 and the fourth substrate 24 may respectively comprise glass, quartz, sapphire, ceramics, plastics, polycarbonate (PC), polyimide (PI), polypropylene (PP), polyethylene terephthalate (PET), polymethylmethacrylate (PMMA), ajinomoto build-up film (ABF), other suitable materials or a combination thereof, but the present disclosure is not limited thereto. In addition, circuits, pads, electronic components, transistors, other suitable components or a combination thereof may be selectively further disposed on the first substrate 21, the second substrate 22, the third substrate 23 and the fourth substrate 24 respectively, but the present disclosure is not limited thereto.

In the present disclosure, the light emitting elements 3 may further comprise a light emitting diode, which may comprise, for example, an organic light emitting diode (OLED), a mini LED, a micro LED, a quantum dot LED (which may comprise QLED or QDLED), fluorescence, phosphors, other suitable material or a combination thereof, but the present disclosure is not limited thereto. In the present disclosure, the light emitting elements 3 may respectively emit the same color or different colors of light such as red, blue, green or white, but the present disclosure is not limited thereto. The light emitting element 3 may be electrically connected to a component (for example, a transistor) on a corresponding substrate (for example, the first substrate 21, the second substrate 22, the third substrate 23 and/or the fourth substrate 24), so that the light emitting element 3 may be driven, for example, by the transistor. In the present disclosure, the light emitting elements 3 shown in FIG. 1A are arranged in a 3×6 array on a substrate as an example, but the present disclosure is not limited thereto. In other embodiments, the number and/or the arrangement of the light emitting elements 3 may be adjusted (for example, increased or decreased) according to the needs. In some embodiments, the light emitting element 3 may, for example, comprise a semiconductor unit or a package after the semiconductor unit is packaged, such as mini/micro LED in package (MIP) or integrated matrix devices (IMD).

In the present disclosure, the material of the cover layer 4 may comprise a transparent material, and a suitable material may comprise, for example, glass glue, optical glue, silicone glue, hot melt glue, AB glue, light curing glue, polymer glue, resin, acrylic, polymethyl methacrylate (PMMA), poly-para-xylylene, parylene or a combination thereof, but the present disclosure is not limited thereto. In the present disclosure, the refractive index n1 of the cover layer 4 may be greater than 1 and less than 2.4 (that is, 1<n1<2.4), for example, greater than 1 and less than or equal to 2 (that is, 1<n1≤2), greater than 1 and less than or equal to 1.7 (that is, 1<n1≤1.7), or greater than or equal to 1.3 and less than or equal to 1.6 (that is, 1.3≤n1≤1.6), but the present disclosure is not limited thereto. When the refractive index of the cover layer 4 meets the aforesaid requirements, the light emitting efficiency of light emitting element 3 can be improved.

In the present disclosure, the transmittance of the low transmittance film 5 may be less than 70%, for example, less than or equal to 65%, less than or equal to 60%, less than or equal to 55% or less than or equal to 50%, but the present disclosure is not limited thereto. When the transmittance of the low transmittance film 5 meets the aforesaid requirements, the transmittance of the low transmittance film 5 can be lower under visual observation, the tiling gaps (for example, the first tiling gap G1, the second tiling gap G2, the third tiling gap G3 and the fourth tiling gap G4) observed by human eyes can be reduced, thereby achieving the effect of improving the display taste. In some embodiments, when the transmittance of the low transmittance film 5 meets the aforesaid requirement, the effect close to pure black or pure gray can be achieved, so the tiling gap observed by human eyes can be reduced, thereby achieving the effect of improving the display taste. In one embodiment of the present disclosure, the low transmittance film 5 may be a circular polarizer, a wavelength conversion film, a black PET film, a metal mesh or a combination thereof, but the present disclosure is not limited thereto. The term “transmittance” may refer to, for example, the transmittance of a component to light within a wavelength range (for example, the light with wavelengths less than or equal to 360 nm, the light with wavelengths greater than or equal to 830 nm, the light with wavelengths 380 nm to 780 nm or a combination thereof, but the present disclosure is not limited thereto).

In one embodiment of the present disclosure, as shown in FIG. 1A and FIG. 1B, the electronic device may further comprise a circuit board 1, wherein the first substrate 21 and the second substrate 22 are respectively disposed on the circuit board 1 and electrically connected to the circuit board 1. More specifically, as shown in FIG. 1B, the circuits and/or components on the first substrate 21 and the second substrate 22 can be electrically connected to the circuit board 1 through an electrical connector C1, so that the signal can be transmitted from the circuit board 1 to the light emitting element 3 on the corresponding substrate for driving. Similarly, the third substrate 23 and the fourth substrate 24 may also be disposed on the circuit board 1 respectively, and electrically connected to the circuit board 1 through another connector (not shown in the figure) to drive the light emitting elements 3 on the third substrate 23 and/or the fourth substrate 24. By assembling a plurality of substrates containing the light emitting elements 3 on a circuit board 1 in a tiled manner to form a tiled device, when a single light emitting element 3 is damaged, it can be repaired by replacing the corresponding single substrate, thereby reducing the cost of scrapping all the light emitting elements 3 due to one light emitting element 3 damaged in the past. In the present disclosure, the circuit board 1 may be a printed circuit board (PCB), a flexible printed circuit board (FPC) or a combination thereof, but the present disclosure is not limited thereto.

In one embodiment of the present disclosure, as shown in FIG. 1B, the electronic device may further comprise an adhesion layer 6 disposed between the circuit board 1 and the first substrate 21 and between the circuit board 1 and the second substrate 22. The adhesion layer 6 may be used to fix the first substrate 21 and the second substrate 22 on the circuit board 1. Similarly, the adhesion layer 6 may also be disposed between the circuit board 1 and the third substrate 23 and the circuit board 1 and the fourth substrate 24, which is not described again here.

In the present disclosure, the material of the adhesion layer 6 may comprise glass glue, optical glue, silicone glue, adhesive tape, hot melt glue, AB glue, two-component adhesive, polymer adhesive, other suitable adhesive material or a combination thereof, but the present disclosure is not limited thereto. In one embodiment of the present disclosure, the transmittance of the adhesion layer 6 may be greater than 30%, for example, greater than or equal to 35%, greater than or equal to 40%, greater than or equal to 45% or greater than or equal to 50%, but the present disclosure is not limited thereto. In one embodiment of the present disclosure, the adhesion layer 6 may selectively be an adhesive material with reflective effect, and the reflectivity thereof may be greater than 20%, for example, greater than or equal to 25%, greater than or equal to 30%, greater than or equal to 35% or greater than or equal to 40%, but the present disclosure is not limited thereto. When the adhesion layer 6 has reflective effect, the adhesion layer 6 can reflect the light emitted downward from the light emitting element 3 and guide the light upward, thereby improving the light extraction efficiency of the electronic device.

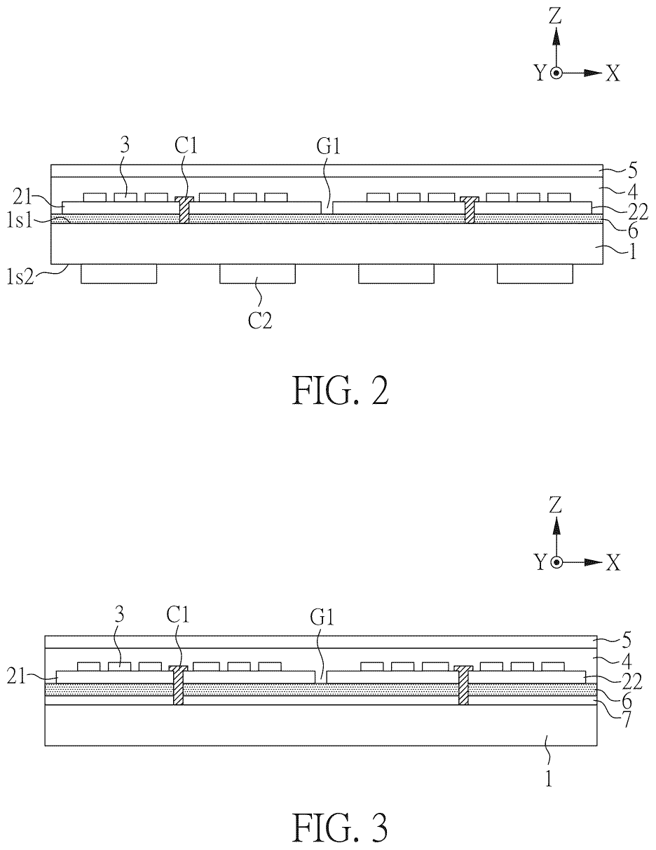

FIG. 2 is a cross-sectional schematic view of a part of an electronic device according to one embodiment of the present disclosure. The electronic device of FIG. 2 is similar to that of FIG. 1B except for the following differences.

In one embodiment of the present disclosure, as shown in FIG. 2, the electronic device may further comprise an integrated circuit (IC) C2 disposed on one side of the circuit board 1 and electrically connected to the light emitting element 3. More specifically, the circuit board 1 has a first surface 1s1 and a second surface 1s2 opposite to the first surface 1s1, wherein the first substrate 21 and the second substrate 22 are disposed on the first surface 1s1 of the circuit board 1, and the integrated circuit C2 is disposed on the second surface 1s2 of the circuit board 1. The integrated circuit C2 may be electrically connected to the electrical connector C1 and the light emitting element 3 through the circuit board 1, thereby transmitting signal to the light emitting element 3 for driving. In some embodiments, even not shown in the figure, the first substrate 21, the second substrate 22 and the integrated circuit C2 may be disposed on the first surface 1s1 of the circuit board 1. In some embodiments, even not shown in the figure, the first substrate 21, the second substrate 22 and a portion of the integrated circuit C2 may be disposed on the first surface 1s1 of the circuit board 1, and a portion of the integrated circuit C2 is disposed on the second surface 1s2 of the circuit board 1.

In the present disclosure, other detailed features of the electronic device are as described above and are not described again here.

FIG. 3 is a cross-sectional schematic view of a part of an electronic device according to one embodiment of the present disclosure. The electronic device of FIG. 3 is similar to that of FIG. 1B except for the following differences.

In one embodiment of the present disclosure, as shown in FIG. 3, the electronic device may further comprise a reflective layer 7 disposed between the adhesion layer 6 and the circuit board 1. The reflective layer 7 may reflect the light emitted downward by the light emitting element 3 and guide the light upward, thereby improving the light extraction efficiency of the electronic device.

In the present disclosure, the material of the reflective layer 7 may comprise a metal, a metal oxide, white ink, other reflective materials or a combination of the above. The suitable metal may comprise, for example, gold, silver, copper, palladium, platinum (Pt), ruthenium (Ru), aluminum, cobalt, nickel, titanium, molybdenum (Mo), manganese, zinc, an alloy thereof or a combination thereof, but the present disclosure is not limited thereto. The suitable metal oxide may comprise, for example, zinc oxide, titanium oxide or a combination thereof, but the present disclosure is not limited thereto. The suitable white ink may comprise, for example, white polyimide, resin, other suitable material or a combination thereof, but the present disclosure is not limited thereto. In the present disclosure, the reflectivity of the reflective layer 7 may be greater than 30%, for example, greater than or equal to 35%, greater than or equal to 40%, greater than or equal to 45% or greater than or equal to 50%, but the present disclosure is not limited thereto. In the present disclosure, the reflective layer 7 may be formed by, for example, chemical vapor deposition, physical vapor deposition, sputtering, coating, or a combination thereof, but the present disclosure is not limited thereto. Suitable coating methods may comprise, for example, dip coating, spin coating, roller coating, doctor blade coating, spray coating or a combination thereof, but the present disclosure is not limited thereto.

In the present disclosure, other detailed features of the electronic device are as described above and are not described again here.

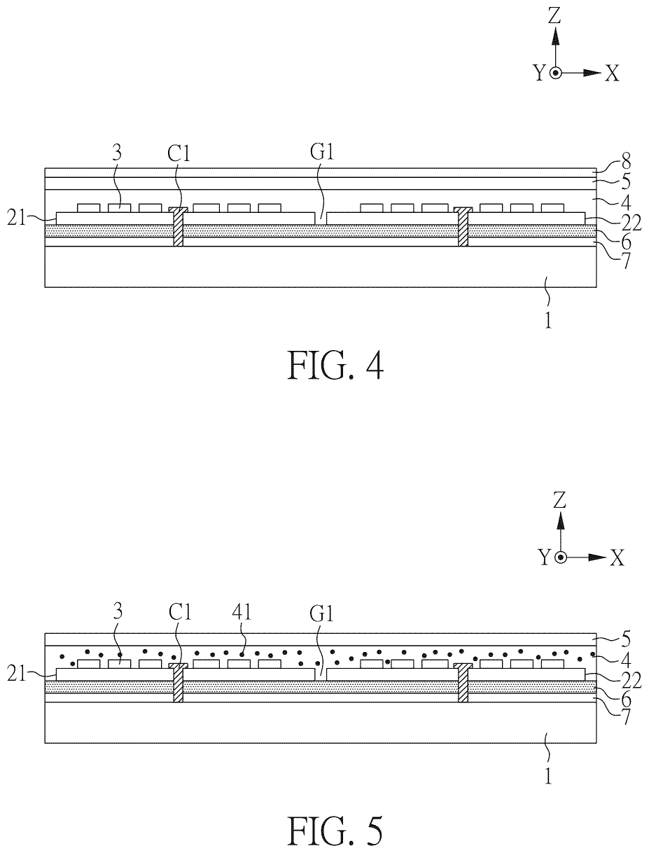

FIG. 4 is a cross-sectional schematic view of a part of an electronic device according to one embodiment of the present disclosure. The electronic device of FIG. 4 is similar to that of FIG. 3 except for the following differences.

In one embodiment of the present disclosure, as shown in FIG. 4, the electronic device may further comprise an anti-glare film 8 disposed on the low transmittance film 5. The anti-glare film 8 may be used to improve the glare of the electronic device, thereby enhancing the display taste of electronic devices.

In the present disclosure, the anti-glare film 8 may comprise transparent organic material or inorganic material. The haze of the anti-glare film 8 may be greater than 20%, for example, greater than or equal to 25%, greater than or equal to 30% or greater than or equal to 35%, but the present disclosure is not limited thereto. In the present disclosure, the anti-glare film 8 may be formed by screen printing, coating or other suitable methods. In one embodiment of the present disclosure, the haze of the anti-glare film 8 may be obtained by hard coating, texturing, sandblasting or other suitable processes on the material of the anti-glare film 8, and/or by applying diffusion particles into the material of the anti-glare film 8, but the present disclosure is not limited thereto.

In the present disclosure, other detailed features of the electronic device are as described above and are not described again here.

FIG. 5 is a cross-sectional schematic view of a part of an electronic device according to one embodiment of the present disclosure. The electronic device of FIG. 5 is similar to that of FIG. 3 except for the following differences.

In one embodiment of the present disclosure, as shown in FIG. 5, the cover layer 4 of the electronic device may comprise a plurality of diffusion particles 41. The diffusion particles 41 can uniformize the light emitted by the light emitting element 3 and/or improve the visual angle difference, thereby improving the light emitting efficiency and/or display quality of the electronic device.

In the present disclosure, other detailed features of the electronic device are as described above and are not described again here.

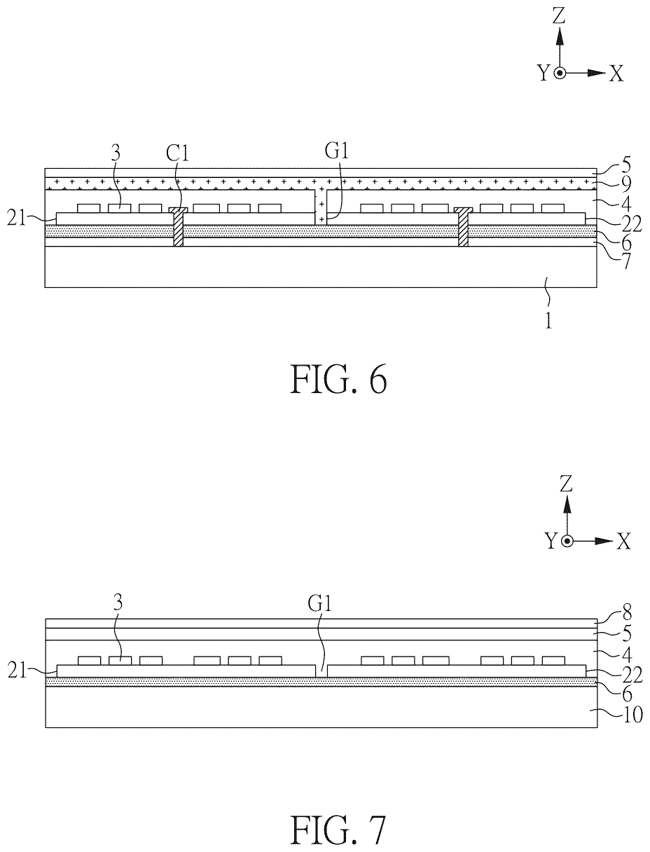

FIG. 6 is a cross-sectional schematic view of a part of an electronic device according to one embodiment of the present disclosure. The electronic device of FIG. 6 is similar to that of FIG. 3 except for the following differences.

In one embodiment of the present disclosure, as shown in FIG. 6, the electronic device may further comprise another cover layer 9 disposed on the cover layer 4, and the cover layer 9 is further disposed in the tiling gap (for example, the first tiling gap G1) between the first substrate 21 and the second substrate 22. More specifically, the cover layer 4 is firstly disposed on the first substrate 21 and the second substrate 22 respectively, the first substrate 21 and the second substrate 22 are then disposed on the circuit board 1, and the cover layer 9 is further disposed on the cover layer 4 and in the first tiling gap G1 between the first substrate 21 and the second substrate 22. Then, the low transmittance film 5 is disposed on the cover layer 9 to complete the electronic device shown in FIG. 6.

In the present disclosure, the material of the cover layer 9 may be a transparent material, and suitable material may comprise, for example, glass glue, optical glue, silicone glue, hot melt glue, AB glue, light curing glue, polymer glue, resin, acrylic, polymethyl methacrylate (PMMA), poly-para-xylylene (parylene) or a combination thereof, but the present disclosure is not limited thereto. In the present disclosure, the refractive index n2 of the cover layer 9 may be greater than 1 and less than the refractive index n1 of the cover layer 4 (that is, 1<n2<n1). For example, the refractive index n2 of the cover layer 9 may be greater than 1 and less than 2.3 (that is, 1<n2<2.3), greater than 1 and less than 2 (that is, 1<n2<2), greater than 1 and less than 1.7 (that is, 1<n2<1.7), greater than 1 and less than 1.6 (that is, 1<n2<1.6), greater than 1 and less than 1.5 (that is, 1<n2<1.5) or greater than 1 and less than 1.3 (that is, 1<n1<1.3), but the present disclosure is not limited thereto. When the refractive indexes of the cover layer 4 and the cover layer 9 meet the aforesaid requirements, the light extraction efficiency of the electronic device can be improved.

In one embodiment of the present disclosure, even not shown in the figure, the cover layer 4 of the electronic device shown in FIG. 6 may selectively comprise a plurality of diffusion particles 41 (as shown in FIG. 5) to uniformize the light emitted by the light emitting element 3 and/or improve the color difference of the viewing angle, thereby improving the light emitting efficiency and/or display quality of the electronic device.

In the present disclosure, other detailed features of the electronic device are as described above and are not described again here.

FIG. 7 is a cross-sectional schematic view of a part of an electronic device according to one embodiment of the present disclosure. The electronic device of FIG. 7 is similar to that of FIG. 1B except for the following differences.

In one embodiment of the present disclosure, as shown in FIG. 7, the first substrate 21 and the second substrate 22 of the electronic device may be a substrate comprising circuits and transistors. Thus, the first substrate 21 and the second substrate 22 may be disposed on a structure back plate 10 directly through an adhesion layer 6. Thus, the flatness and/or structural strength of the electronic devices can be improved. In the present disclosure, the electronic device can be electrically connected to an external signal source directly through the components on the first substrate 21 and the second substrate 22 to drive the light emitting element 3. Thus, the circuit board 1 and the electrical connector C1 shown in FIG. 1B can be omitted, but the present disclosure is not limited thereto.

In one embodiment of the present disclosure, as shown in FIG. 7, the electronic device may further comprise an anti-glare film 8 disposed on the low transmittance film 5. The anti-glare film 8 may be used to improve the glare of the electronic device, thereby enhancing the display taste of electronic devices.

In the present disclosure, the material of the structure back plate 10 may comprise a metal, a metal oxide, polycarbonate (PC), polyimide (PI), polypropylene (PP), polyethylene terephthalate (PET), other plastic or polymer, or a combination thereof, but the present disclosure is not limited thereto. In the present disclosure, the features of the anti-glare film 8 can be referred to above and are not described again here. In addition, other detailed features of the electronic device are as described above and are not described again here.

The present disclosure forms a tiled device by assembling a plurality of substrates containing light emitting elements 3 in a tiled manner, which can reduce the cost caused by the defective rate. In addition, by arranging the low transmittance film 5 to overlap the tiling gap, the tiling gap observed by the human eye can be reduced, thereby achieving the effect of improving the display quality.

The above specific embodiments should be construed as merely illustrative and not limiting in any way the remainder of the present disclosure.

Although the present disclosure has been explained in relation to its embodiment, it is to be understood that many other possible modifications and variations can be made without departing from the spirit and scope of the disclosure as hereinafter claimed.

1. An electronic device, comprising:
a first substrate;
a second substrate disposed adjacent to the first substrate, wherein a tiling gap is between the first substrate and the second substrate;
a plurality of light emitting elements respectively disposed on the first substrate and the second substrate;
a cover layer disposed on the first substrate and the second substrate and covering the plurality of light emitting elements; and
a low transmittance film disposed on the cover layer, wherein the low transmittance film and the tiling gap are overlapped in a normal direction of the electronic device.

2. The electronic device of claim 1, wherein the low transmittance film has a transmittance less than 70%.

3. The electronic device of claim 1, wherein the low transmittance film is a circular polarizer, a wavelength conversion film, a black PET film, a metal mesh or a combination thereof.

4. The electronic device of claim 1, wherein the cover layer has a refractive index greater than 1 and less than 2.4.

5. The electronic device of claim 1, wherein the cover layer comprises a plurality of diffusion particles.

6. The electronic device of claim 1, further comprising a circuit board, wherein the first substrate and the second substrate are respectively disposed on the circuit board and electrically connected to the circuit board.

7. The electronic device of claim 6, further comprising an integrated circuit disposed on one side of the circuit board and electrically connected to the plurality of light emitting elements.

8. The electronic device of claim 6, wherein the plurality of light emitting elements on the first substrate and the second substrate are electrically connected to the circuit board through an electrical connector.

9. The electronic device of claim 6, further comprising an adhesion layer disposed between the circuit board and the first substrate and between the circuit board and the second substrate.

10. The electronic device of claim 9, wherein a transmittance of the adhesion layer is greater than 30%.

11. The electronic device of claim 9, wherein a reflectivity of the adhesion layer is greater than 20%.

12. The electronic device of claim 9, further comprising a reflective layer disposed between the adhesion layer and the circuit board.

13. The electronic device of claim 12, wherein a reflectivity of the reflective layer is greater than 30%.

14. The electronic device of claim 1, further comprising an anti-glare film disposed on the low transmittance film.

15. The electronic device of claim 14, wherein a haze of the anti-glare film is greater than 20%.

16. The electronic device of claim 1, further comprising another cover layer disposed on the cover layer and further disposed in the tiling gap between the first substrate and the second substrate.

17. The electronic device of claim 16, wherein the another cover layer has a refractive index greater than 1 and less than a refractive index of the cover layer.

18. The electronic device of claim 1, wherein the cover layer comprises a plurality of diffusion particles.

19. The electronic device of claim 1, wherein the first substrate and the second substrate are disposed on a structure back plate.

20. The electronic device of claim 19, wherein the first substrate and the second substrate are disposed on the structure back plate directly through an adhesion layer.
